(19) United States
(12) Patent Application Publication
(10) Pub. No.: US 2014/0342167 A1
(43) Pub. Date: Nov. 20, 2014

(54) SILICON-RICH ANTIREFLECTIVE COATING MATERIALS AND METHOD OF MAKING SAME

(71) Applicant: Dow Corning Corporation, Midland, MI (US)

(72) Inventors: Ming-Shin Tzou, Midland, MI (US); Xiaobing Zhou, Midland, MI (US)

(21) Appl. No.: 14/370,540

(22) PCT Filed: Jan. 17, 2013
(86) PCT No.: PCT/US2013/021829

§ 371 Date: Jul. 3, 2014

Related U.S. Application Data
(60) Provisional application No. 61/587,744, filed on Jan. 18, 2012.

(51) Int. Cl. C09D 183/14; G03F 7/075; H01L 21/02; G03F 7/09

(52) U.S. Cl. CPC C09D 183/14; G03F 7/091; G03F 7/0752; H01L 21/02118; H01L 21/02282; H01L 21/02318
USPC 428/447; 524/588; 524/268; 438/781

(57) ABSTRACT

An antireflective coating (ARC) formulation for use in photolithography is provided that comprises silicon-rich polysilanesiloxane resins dispersed in a solvent, as well as a substrate having a surface coated with the ARC formulation and a method of applying the ARC formulation to said surface to form an ARC layer. The polysilanesiloxane resins comprise a first component defined by structural units of (R′)₂SiO₂; a second component defined by structural units of (R″)SiO₃ and a third component defined by structural units of (R′″)_{q+2}Si₂O_{4-q}. In these polysilanesiloxane resins, the R′, R″, and R′″ are independently selected to be hydrocarbon or hydrogen (H) groups; and the subscript q is 1 or 2. Alternatively, the R′, R″, and R′″ are independently selected as methyl (Me) or hydrogen (H) groups. Typically, the first component is present in a molar ratio x, the second component is present in molar ratio y, and the third component is present in a molar ratio z, such that (x+y+z)=1, x<y, and x<z. The polysilanesiloxane resin has a silicon content that is greater than or equal to about 42 wt. %.

This disclosure relates generally to photolithography. More specifically, this disclosure relates to the preparation of silicon-rich resins and their use as antireflective coatings during photolithographic processing of an electronic device.

With the continuing demand for smaller feature sizes in the semiconductor industry, photolithography using 193 nm light has recently emerged as a technology capable of producing devices with sub-100 nm features. The use of such a short wavelength of light requires the inclusion of a bottom antireflective coating capable of reducing the occurrence of reflecting light onto the substrate, as well as damping of the photoresist swing cure by absorbing light that passes though the photoresist. Antireflective coatings (ARCs) consisting of organic-based or inorganic-based materials are commercially available. Conventional inorganic-based ARCs, which exhibit good etch resistance, are typically deposited using a chemical vapor deposition (CVD) process. Thus, these inorganic-based ARCs are subject to all of the integration disadvantages associated with extreme topography. On the other hand, conventional organic-based ARCs are typically applied using spin-on processes. Thus, organic-based ARCs exhibit excellent fill and planarization properties, but suffer from poor etch selectivity when used in conjunction with an organic photoresist. As a result, the development of new materials that offer the combined advantages of organic-based and inorganic-based ARCs is continually desirable.

### BRIEF SUMMARY OF THE INVENTION

In overcoming the enumerated drawbacks and other limitations of the related art, the present disclosure generally provides an antireflective coating (ARC) formulation for use in photolithography that comprises greater than or equal to about 42 wt. % silicon, but no more than about 90 wt. %. The ARC formulation comprises a polysilanesiloxane resin dispersed in a solvent. The polysilanesiloxane resin includes a first component defined by structural units of (R′)₂SiO₂; a second component defined by structural units of (R″)SiO₃; and a third component defined by structural units of (R′″)_{q+2}Si₂O_{4-q}. In these structural units, the R′, R″, and R′″ are independently selected to be hydrocarbon or hydrogen (H) groups; and the subscript q is 1 or 2. Alternatively, the R′, R″, and R′″ are independently selected as methyl (Me) or hydrogen (H) groups. Typically, the first component is present in a molar ratio x, the second component is present in molar ratio y, and the third component is present in a molar ratio z, such that (x+y+z)=1, x<y, and x<z.

According to one aspect of the present disclosure, one example among many of polysilanesiloxane resins prepared according to the teachings of the present disclosure includes R′ selected such that the structural units of (R′)₂SiO₂ are (Me)(H)SiO₂; R″ selected such that the structural units of (R″)SiO₃ are a mixture of (H)SiO₃ and (Me)SiO₃; and R′″ and q selected such that the structural units of (R′″ )_{q+2}Si₂O_{4-q} are a mixture of (Me)₃Si₂O₃ and (Me)₄Si₂O₂. In this one example, the molar ratio of x equals 0.1, the molar ratio of y equals 0.45, and the molar ratio of z equals 0.45.

According to another aspect of the present disclosure, a method of forming an antireflective coating (ARC) is provided. This method generally comprises the steps of: providing a polysilanesiloxane resin as further described herein dispersed in a solvent to form an ARC formulation; providing an electronic device; applying the ARC formulation to the surface of the electronic device to form a film; removing the solvent from the film; and curing the film to form the antireflective coating. Alternatively, the ARC formulation is applied to the surface of the electronic device by spin-coating and the film is cured at a temperature less than or equal to 250° C. Optionally, the method may further comprise the step of incorporating additives into the ARC formulation or the step of placing the film under an inert atmosphere prior to curing the film.

According to yet another aspect of the present disclosure, a substrate coated with an antireflective coating (ARC) layer is disclosed, wherein the ARC layer comprises a polysilanesiloxane resin enriched with silicon. Alternatively, the polysilanesiloxane may have greater than or equal to about 42 wt. % silicon. This polysilanesiloxane resin comprises D^{R}′, T^{R}″, and PSSX^{R}′″ structural units according to the formula:

(D^{R}′)ₓ (T^{R}″)_{y} (PSSX^{R}′″)_{z}

wherein (D^{R}′)ₓ represents structural units of (R′)₂SiO₂; (T^{R}″)_{y} represents structural units of (R″)SiO₃; and (PSSX^{R}′″)_{z} represents structural units of (R′″ )_{q+2}Si₂O_{4-q}; where R′, R″, and R′″ are independently selected to be hydrocarbon or hydrogen groups and the subscript q is 1 or 2 with the subscripts x, y, and z representing mole fractions that are greater than zero and less than one, such that (x+y+z)=1. Alternatively, R′, R″, and R′″ are independently selected as methyl (Me) or hydrogen (H) groups.

One example, among others, of a polysilanesiloxane resin coated on the substrate includes R′ selected such that the structural units of (R′)₂SiO₂ are (Me)(H)SiO₂; R″ selected such that the structural units of (R″)SiO₃ are a mixture of (H)SiO₃ and (Me)SiO₃; and R′″ and q selected such that the structural units of (R′″ )_{q+2}Si₂O_{4-q} are a mixture of (Me)₃Si₂O₃ and (Me)₄Si₂O₂. The polysilanesiloxane resin may have the (D^{R}′)ₓ, (T^{R}″)_{y}, and (PSSX^{R}′″)_{z} structural units present such that x<y, and x<z. Alternatively, the molar ratio of x equals 0.1, the molar ratio y equals 0.45, and the molar ratio z equals 0.45.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic representation of a method for preparing an antireflective coating including polysilansiloxane resins according to the teachings of the present disclosure.

### DETAILED DESCRIPTION OF THE INVENTION

The following description is merely exemplary in nature and is in no way intended to limit the present disclosure or its application or uses. It should be understood that throughout the description and drawings, corresponding reference numerals indicate like or corresponding parts and features.

The present disclosure generally provides an antireflective coating (ARC) formulation for use in photolithography. The formulation of the antireflective coating includes a polysilanesiloxane resin dispersed in a solvent. The polysilanesiloxane resin generally comprises a first component defined by structural units of (R′)₂SiO₂; a second component defined by structural units of (R″)SiO₃ and a third component defined by structural units of (R′″ )_{q+2}Si₂O_{4-q}. In this polysilanesiloxane resin, the R′, R″, and R′″ are independently selected to be hydrocarbon or hydrogen (H) groups; and the subscript q is 1 or 2. Alternatively, the R′, R″, and R′″ are independently selected as methyl (Me) or hydrogen (H) groups. The polysilanesiloxane resin of the present disclosure comprises greater than or equal to about 42 wt. % silicon, but no more than about 90 wt. %.

According to one aspect of the present disclosure, the ARC formulation includes polysilanesiloxane resins dispersed in a solvent in which R′ is selected such that the structural units of (R′)₂SiO₂ in the first component are (Me)(H)SiO₂; R″ is selected such that the structural units of (R″)SiO₃ in the second component are a mixture of (H)SiO₃ and (Me)SiO₃; and R′″ and q are selected such that the structural units of (R′″ )_{q+2}Si₂O_{4-q} in the third component are a mixture of (Me)₃Si₂O₃ and (Me)₄Si₂O₂.

The amount of the first, second, and third components present in the polysilanesiloxane resins used in the ARC formulation may be predetermined. The first component is present in the ARC formulation in a molar ratio x, the second component is present in molar ratio y, and the third component is present in a molar ratio z, such that (x+y+z)=1, x<y, and x<z. Alternatively, the molar ratio of x is approximately 0.1, the molar ratio of y is approximately 0.45, and the molar ratio of z is approximately 0.45.

The antireflective coating (ARC) layer formed from these polysilanesiloxane resins exhibit a high etch contrast relative to the organic photoresists subsequently deposited on top of the ARC layer during a photolithographic process. Although not want to be held to theory, it is believed that a higher silicon (Si) content in the polysilanesiloxane resins of the present disclosure increases the etch rate of the ARC layer and further enhances the etch contrast between the ARC layer and the photoresist. In addition to absorption of 193 nm light, the ARC layer formed from the polysilanesiloxane resins of the present disclosure meets the basic requirements for use as an antireflective coating. Two of these basic requirements include: 1) the ARC layer as applied to an electronic device is cured at a temperature of 450° C. or lower, alternatively at 250° C. or lower, alternatively the temperature is equal to or higher than the boiling point exhibited by the solvent present in the ARC formulation; and 2) the cured ARC layer resists subsequent exposure to solvents and/or etchants, including but not limited to, propylene glycol monomethyl ether acetate (PGMEA) and tetramethylammonium hydroxide (TMAH).

Another potential application for the polysilanesiloxane resins of the present disclosure with their high silicon content is etch transfer. Double patterning may potentially extend current 193 nm dry lithography to a resolution of 22 nm tech node or below. Etch transfer layers that have higher silicon contents and higher etch sensitivity may be used in this application.

The polysilanesiloxane resins may be prepared from the hydrolysis and condensation of appropriate halo- and/or alkoxy-silanes similar to the method used to produce silsesquioxane resins as described in U.S. Pat. No. 5,762,697 to Sakamoto et al., U.S. Pat. No. 6,281,285 to Becker et al. and U.S Pat. No. 5,010,159 to Bank et al., the disclosure of which is incorporated herein by reference. Residual hydroxyl or alkoxy groups may remain in the polysilanesiloxane resin as a result of incomplete hydrolysis or condensation. Typically the polysilanesiloxane resins of the present disclosure contain less than about 40 mole % of units containing hydroxyl or alkoxy groups, alternatively less than about 20 mole %, alternatively less than about 10 mole %, alternatively less than about 5 mole %, alternatively less than about 1 mole %.

The polysilanesiloxane resins prepared according to the method of the present disclosure exhibit a weight average molecular weight (Mw) in the range of 500 to 400,000, alternatively in the range of 500 to 100,000, alternatively in the range of 700 to 30,000. One skilled in the art will understand that such determination of molecular weight can be made by gel permeation chromatography using refractive index (RI) detection and polystyrene standards.

The amount of water present during the hydrolysis reaction is typically in the range of 0.5 to 2 moles water per mole of halo or alkoxy groups present in the silane reactants, alternatively 0.5 to 1.5 moles per mole of halo or alkoxy groups in the silane reactants.

The time to form the polysilanesiloxane resins is dependent upon a number of factors such as the temperature, the type and amount of silane reactants, and the amount of catalyst, if present. The reaction is allowed to proceed for a time that is sufficient for essentially all of the halo and/or alkoxy groups to undergo hydrolysis reactions. Typically the reaction time is from about two minutes to about ten hours, alternatively 10 minutes to 1 hour. One skilled in the art will be able to readily determine the time necessary to complete the reaction.

The reaction to produce the polysilanesiloxane resins can be carried out at any temperature so long as it does not cause significant gellation or curing of the polysilanesiloxane resins. The temperature at which the reaction is carried out is typically in the range of 25° C. up to the reflux temperature of the reaction mixture. The reaction may be carried out by heating under reflux for 10 minutes to 1 hour.

In order to facilitate the completion of the hydrolysis and condensation reaction, a catalyst may be used when desired. The catalyst can be a base or an acid such as a mineral acid or inorganic acid. Useful mineral acids include, but are not limited to, HCl, HF, HBr, HNO₃, and H₂SO₄, among others, alternatively the mineral acid is HCl. When used, the amount of catalyst is typically about 0.05 wt. % to about 1 wt. % based on the total weight of the reaction mixture. Following completion of the reaction, the catalyst may be optionally removed. Methods for removing the catalyst are well known to one skilled in the art and include neutralization, stripping or water washing or combinations thereof.

Since the silane reactants are either not soluble or only sparingly soluble in water, the reaction is carried out in a solvent. The solvent in which the polysilanesiloxane resins are formed is present in any amount sufficient to dissolve the silane reactants. Typically the solvent is present from 1 to 99 weight percent, alternatively from about 70 to 90 wt. %, based on the total weight of the reaction mixture. Examples of organic solvents include, but are not limited to, saturated aliphatics, such as n-pentane, hexane, n-heptane, and isooctane; cycloaliphatics, such as cyclopentane and cyclohexane; aromatics, such as benzene, toluene, xylene, and mesitylene; ethers, such as tetrahydrofuran, dioxane, ethylene glycol dietheyl ether, and ethylene glycol dimethyl ether; ketones, such as methylisobutyl ketone (MIBK) and cyclohexanone; halogen substituted alkanes, such as trichloroethane; halogenated aromatics, such as bromobenzene and chlorobenzene; and esters, such as propylene glycol monomethyl ether acetate (PGMEA), isobutyl isobutyrate, and propyl propronate. Useful silicone solvents may be exemplified by, but not limited to, cyclic siloxanes, such as octamethylcyclotetrasiloxane and decamethylcyclopentasiloxane. A single solvent may be used or a mixture of solvents may be used.

In the process of preparing the polysilanesiloxane resins, after the reaction is complete, volatiles may be removed from the polysilanesiloxane resin solution under reduced pressure. Such volatiles include alcohol by-products, excess water, catalyst, hydrochloric acid (if chlorosilane reactants are used) and solvents. Methods for removing these volatiles are known to one skilled in the art and include, for example, distillation or stripping under reduced pressure.

In order to increase the molecular weight of the polysilanesiloxane resins and/or to improve the storage stability of the resins, a “bodying” step may be utilized. Such a bodying step may involve allowing the reaction to continue for an extended period of time with heating from 40° C. up to the reflux temperature of the solvent. The bodying step may be carried out subsequent to the reaction step or as part of the reaction step. Typically, the bodying step is carried out for a period of time in the range of 10 minutes to 6 hours, alternatively 20 minutes to 3 hours.

Following the reaction to produce the polysilanesiloxane resins, a number of optional steps may be carried out to obtain the polysilanesiloxane resins in the desired form. For example, the polysilanesiloxane resins may be recovered in solid form by removing the solvent. The method of solvent removal is not critical, and numerous methods are well known in the art (e.g. distillation under heat and/or vacuum). Once the polysilanesiloxane resins are recovered in a solid form, the resins can be optionally re-dissolved in the same or another solvent as desired for a particular use. Alternatively, if a different solvent, other than the solvent used in the reaction, is desired for the final product, a solvent exchange may be done by adding a secondary solvent and removing the first solvent through distillation, for example. Additionally, the resin concentration in solvent can be adjusted by removing some of the solvent or adding additional amounts of solvent.

The solvent used to disperse the polysilanesiloxane resins in the ARC formulation may be the same solvent used to prepare the polysilanesiloxane resins or a different organic or silicone solvent. Alternatively, several examples of useful solvents include, but are not limited to, 1-methoxy-2-propanol, propylene glycol monomethyl ethyl acetate (PGMEA), gamma-butyrolactone, ethoxy ethyl proprionate (EEP), and cyclohexanone, among others. Alternatively, the solvent is propylene glycol monomethyl ether acetate (PGMEA) or ethoxy ethyl propionate (EEP). The ARC formulation typically comprises from 10% to 99.9 wt. % solvent based on the total weight of the ARC formulation, alternatively 80 to 95 wt. % solvent.

The ARC formulation may optionally comprise one or more additives, including but not limited to, cure catalysts, surfactants, dispersants, and other film forming aids. Examples of suitable cure catalysts include, but are not limited to, inorganic acids, photo-acid generators, and thermal acid generators. Alternatively, the cure catalyst may be sulfuric acid (H₂SO₄), (4-ethylthiophenyl) methyl phenyl sulfonium triflate, or 2-naphthyl diphenylsulfonium triflate. Typically, the cure catalyst is present in the ARC formulation in an amount of up to about 1000 ppm, alternatively up to about 500 ppm, based on the total weight of the polysilanesiloxane resins present in the ARC formulation. Several examples of suitable surfactants include, but are not limited to, sodium stearate, sodium dodecyl sulfate, sodium dodecyl benzene sulfonate, laurylamine hydrochloride, trimethyl dodecylammonium chloride, cetyl trimethylammonium bromide, polyoxyethylene alcohol, alkylphenyl ethoxylates, propylene oxide-modified polymethylsiloxanes, dodecyl betaine or lauramidopropyl betaine. Suitable dispersants may include, but not be limited to, the surfactants described above, as well as 2-butyoxyethanol, propylene glycol, tetrahydrofurfuryl alcohol, di(propylene glycol) butyl ether, and 8-cyclodextrin. Examples of suitable film forming aids include polyvinylpyrrolidone, poly(meth)acrylate, and polyacrylamide, among others.

According to another aspect of the present disclosure, a substrate coated with an antireflective coating (ARC) layer is provided. The substrate is an electronic device, including but not limited to, a semiconductor device, such as silicon-based devices and gallium arsenide-based devices intended for use in the manufacture of a semiconductor component. Typically, the device comprises at least one semiconductive layer and a plurality of other layers comprising various conductive, semiconductive, or insulating materials.

The ARC layer generally comprises polysilanesiloxane resins made up of D^{R}′, T^{R}″, and PSSX^{R}′″ structural units according to the formula shown in Equation 1. In Equation 1 and elsewhere in this specification, (D^{R}′)ₓ represents structural units of (R′)2SiO₂; (T^{R}″)_{y} represents structural units of (R″)SiO₃; and (PSSX^{R}′″)_{z} represents structural units of (R′″ )_{q+2}Si₂O_{4-q}. The R′, R″, and R′″ in the structural units are independently selected to be hydrocarbon or hydrogen groups, alternatively, they are independently selected as methyl (Me) or hydrogen (H) groups; the subscript q is 1 or 2; and the subscripts x, y, and z represent mole fractions that are greater than zero and less than one, such that (x+y+z)=1. Alternatively, R′, R″, and R′″ are independently selected to be saturated or unsaturated alkyl groups having between 1-12 carbon atoms, alternatively 1-10 carbon atoms, with such alkyl groups being linear, branched, or cyclic, alternatively, aromatic. Alternatively, the (D^{R}′)ₓ structural units, the (T^{R}″)_{y} structural units, and the (PSSX^{R}′″)_{z} structural units are present in the polysilanesiloxane resins such that x is less than y and x is less than z. Overall, the polysilanesiloxane resins present in the ARC layer comprise greater than or equal to about 42 wt. % , but no more than 90 wt. % silicon.

(D^{R}′)ₓ (T^{R}″)_{y} (PSSX^{R}′″)_{z} Eq. 1

One specific example of an ARC layer is one in which R′ is selected such that the structural units of (R′)₂SiO₂ are (Me)(H)SiO₂; R″ is selected such that the structural units of (R″)SiO₃ are a mixture of (H)SiO₃ and (Me)SiO₃; and R′″ and q are selected such that the structural units of (R′″ )_{q+2}Si₂O_{4-q} are a mixture of (Me)₃Si₂O₃ and (Me)₄Si₂O₂. In this one example, among many, the molar ratio of x:y:z may include x equals 0.1, y equals 0.45, and z equals 0.45.

The ARC layer in which one or more of the (D^{R}′)ₓ, (T^{R}″)_{y}, or (PSSX^{R}′″)_{z} units comprise a hybrid of different unit structures, each unit can be written to more specifically describe the unit structure. In other words, for example, when the unit structure (D^{R}1 is derived from the hydrolysis of a silane in which R′ includes both a methyl and hydrogen group the unit structure can be identified as (D^{meH})ₓ. Similarly, when the unit structure (T^{R}″)_{y} is derived from a mixture of silanes in which R″ is either a methyl group or a hydrogen group, the unit structure can be identified as (T^{Me})_{y-a}(T^{H})_{y-b}, where a+b=y. In the same fashion, when the unit structure (PSSX^{R}′″)_{z} is derived from a mixture of silanes, such as Cl₃Me₃Si₂ and Cl₂Me₄Si₂, the R″ may reflect the identity of the alkyl group and the number thereof per two silicon atoms. In other words, the unit structure can be identified as (PSSX^{Me3Si2})_{z-c}(Pssx^{Me2Si2})_{z-d}, where c+d=z.

One specific example of an ARC layer applied to an electronic device is one identified by polysilanesiloxane resins having the structural units of D^{MeH}_{0.1}T^{Me}_{0.1}T^{H}_{0.35}PSSX^{Me3Si2}_{0.15}PSSX^{Me2Si2}_{0.30}. The amount of silicon present in the polysilanesiloxanes is greater than or equal to about 42 wt. %. Alternatively, the amount of silicon may be no less than about 45 wt. %, 47 wt. %, or 48 wt. %, This ARC layer exhibits good reflective properties and absorption coefficient at 193 nm wavelength of light. Surprisingly, however, the incorporation of the (D^{R}′)ₓ unit in the overall polysilanesiloxane structure of the ARC layer decreases the amount of the layer lost upon exposure to PGMEA or tetramethylammonium hydroxide (TMAH), while maintaining the other mechanical, optical, and chemical properties expected to be exhibited by an ARC layer used in a photolithographic process.

The mechanical, optical, and chemical properties of the ARC layer can be measured using any techniques known to one skilled in the art. Examples of different basic film properties include, but are not limited to, contact angle, surface energy, refractive index (N value) at 193 nm wavelength, extinction coefficient (K value) at 193 nm wavelength, and loss in film thickness caused by exposure to PGMEA or TMAH. The measured properties for ARC layers prepared from conventional polysilanesiloxane formulations (Runs 1-3) and ARC layers (Runs 4-6) prepared according to the teachings of the present disclosure are provided below in Table 1.

TABLE 1
Comparison of Properties Exhibited by Polysilanesiloxane Resins in
Conventional ARC Layers versus ARC Layers of the Present Disclosure

| | | | | Film loss | Film loss | | |
|---|---|---|---|---|---|---|---|
| | | | Molecular | in PGMEA | in TMAH | Refractive | Extinction |
| Run # | Resins | Si wt. % | Weight | (Å) | (Å) | Index, N | Coefficient k |
| 1 | T^{Me}_{0.2}T^{H}_{0.35}PSSX^{Me3Si2}_{0.15}PSSX^{Me2Si2}_{0.30} | 47 | | 201 | 11 | 1.57 | 0.136 |
| 2 | T^{Me}_{0.2}T^{H}_{0.35}PSSX^{Me3Si2}_{0.15}PSSX^{Me2Si2}_{0.30} | 47 | 27,400 | 80 | 9 | 1.552 | 0.135 |
| 3 | T^{Me}_{0.2}T^{H}_{0.35}PSSX^{Me3Si2}_{0.15}PSSX^{Me2Si2}_{0.30} | 47 | 26,100 | 71 | 8 | 1.553 | 0.134 |
| 4 | D^{MeH}_{0.1}T^{Me}_{0.1}T^{H}_{0.35}PSSX^{Me3Si2}_{0.15}PSSX^{Me2Si2}_{0.30} | 48 | 16,600 | 82 | 6 | 1.544 | 0.127 |
| 5 | D^{MeH}_{0.1}T^{Me}_{0.1}T^{H}_{0.35}PSSX^{Me3Si2}_{0.15}PSSX^{Me2Si2}_{0.30} | 48 | 16,800 | 0 | 2 | 1.529 | 0.09 |
| 6 | D^{MeH}_{0.1}T^{Me}_{0.1}T^{H}_{0.35}PSSX^{Me3Si2}_{0.15}PSSX^{Me2Si2}_{0.30} | 48 | 19,900 | −4 | 8 | 1.531 | 0.1 |

In general, the ARC layers (Run No.'s 4-6) exhibit a refractive index (N) that is similar to that exhibited by conventional ARC layers (Run No.'s 1-3) with substantially the same amount of silicon mole wt. % incorporated into the layer. Each of the ARC layers (Run No.'s 1-6) exhibits an acceptable extinction coefficient for absorption of 193 nm light. Run No.'s 4 - 6 exhibits a lower amount of the ARC layer being lost upon exposure either to PGMEA or TMAH than conventional Run No.'s 1-3. These examples demonstrate that the incorporation of a low level of D^{R}′″ structural units into the polysilanesiloxane used to form the ARC layer improves the overall properties exhibited by the ARC layer.

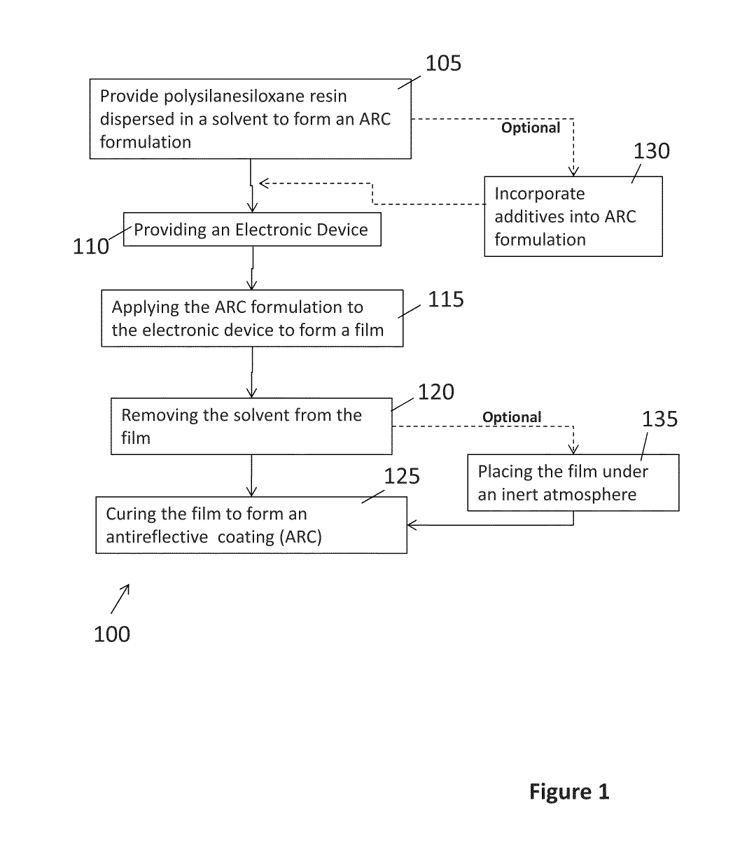

According to another aspect of the present disclosure, a method 100 of forming an antireflective coating (ARC) layer on the surface of an electronic device is provided. Referring to FIG. 1, the method generally comprises the steps of: (105) providing polysilanesiloxane resins dispersed in a solvent to form an ARC formulation; (110) providing an electronic device; (115) applying the ARC formulation to the surface of the electronic device to form a film; (120) removing the solvent from the film; and (125) curing the film to form the antireflective coating (ARC). The ARC formulation comprises the polysilanesiloxane resins as previously described in which the resins include a first component defined by structural units of (R′)₂SiO₂; a second component defined by structural units of (R″)SiO₃ and a third component defined by structural units of (R′″ )_{q+2}Si₂O_{4-q}; where R′, R″, and R′″ are independently selected to be hydrocarbon or hydrogen (H) groups and the subscript q is 1 or 2.

Still referring to FIG. 1, the ARC formulation is formed by providing the polysilanesiloxane resins dispersed in a solvent at a predetermined concentration (step 105). Optionally, additional or other additive(s) may be incorporated into the ARC formulation (step 130). An electronic device is then provided upon which a film from the ARC formulation is subsequently formed (step 115). The ARC formulation may be applied in step 115 to the electronic device by any means known to one skilled in the art. Specific examples of processes useful in applying the ARC formulation to the electronic device in step 115 include, but are not limited to, spin-coating, dip-coating, spay-coating, flow-coating, and screen printing, among others. Alternatively, the method for application of the ARC formulation to the surface of an electronic device is spin coating. In this one example, the application of the ARC formulation involves spinning the electronic device, at 1,000 to 2,000 RPM, and adding the ARC formulation to the surface of the spinning device.

The solvent may be removed from the film (120) using any method known to one skilled in the art, including but not limited to “drying” at room temperature or at an elevated temperature for a predetermined amount of time. The “dry” film is subsequently cured to form the antireflective coating layer on the electronic device (125). Curing in step 125 generally comprises heating the ARC layer to a sufficient temperature for a sufficient duration to lead to sufficient crosslinking such that the polysilanesiloxane resins are essentially insoluble in the solvent from which it was applied. Curing step 125 may take place, for example, by heating the coated electronic device at about 80° C. to 450° C. for about 0.1 to 60 minutes, alternatively about 150° C. to 275° C. for about 0.5 to 5 minutes, alternatively about 200° C. to 250° C. for about 0.5 to 2 minutes. Any method of heating known to those skilled in the art may be used during the curing step 125. For example, the coated electronic device may be placed in a quartz tube furnace, convection oven or allowed to stand on hot plates.

To protect the polysilanesiloxane resins present in the film formed on the substrate from reactions with oxygen or carbon during curing step 125, the curing step can be performed under an inert atmosphere (135). Inert atmospheres useful herein include, but are not limited to nitrogen and argon. By “inert” it is meant that the environment contain less than about 50 ppm and alternatively less than about 10 ppm of oxygen. The pressure at which the curing and removal steps are carried out is not critical. The curing step 125 is typically carried out at atmospheric pressure although sub or super atmospheric pressures may work also.

Typically the antireflective layer after curing is insoluble in conventional photoresist casting solvents. During a photolithographic process a resist coating or layer is formed over the antireflective coating layer. After the resist layer is formed, it is then exposed to radiation, i.e., ultraviolet light (UV) at 193 nm. Typically the resist layer is exposed to the radiation through a mask, thereby allowing a pattern to be formed on the resist layer. After the resist layer has been exposed to radiation, the resist layer typically undergoes a post-exposure bake wherein the resist layer is heated to a temperature in the range of 30° C. to 200° C., alternatively 75° C. to 150° C. for a short period of time, typically 30 seconds to 5 minutes, alternatively 60 to 90 seconds. The exposed resist coating is removed with a suitable developer or stripper solution to produce an image. After the exposed coating has been developed, the remaining resist layer (“pattern”) is typically washed with water to remove any residual developer solution.

The following specific examples are given to illustrate the disclosure and should not be construed to limit the scope of the disclosure. Those skilled-in-the-art, in light of the present disclosure, will appreciate that many changes can be made in the specific embodiments which are disclosed herein and still obtain alike or similar result without departing from or exceeding the spirit or scope of the disclosure.

### Example 1

Synthesis of Conventional TMe_{0.2}T^{H}_{0.35}PSSX^{Me3Si2}_{0.15} PSSX^{Me2Si2}_{0.30} ARC Formulation.

A 3-neck 2-liter flask equipped with a condenser, a heating mantle, a thermal couple, an addition funnel, and a magnet stirrer were assembled to form a reaction system. To this reaction system were added a first solution containing 12.0 grams of 50/50 MeSiCl₃toluene, 20.0 grams of 50/50 HSiCl₃toluene, 247 grams of propylene glycol methyl ether acetate (PGMEA), and 20.06 grams of distilled chloromethyldisilanes, which is composed of 6.7 grams of 1,1,2-trimethyl-trichlorodisilane (Cl₃Me₃Si₂) and 13.3 grams of 1,1,2,2-tetramethyldichlorodisilane (Cl₂Me₄Si₂). A second solution containing 8.35 grams of water and 322.03 grams of PGMEA was fed into the reaction system using a MasterFlex® peristaltic metering pump (Cole-Parmer Instrument Co., Vernon Hills, Ill.) over a period of 1.5 hours to form a reaction mixture. The reaction mixture was allowed to react further at 20° C. for 2 more hours. Then an additional 200 grams of de-ionized water was added into the reaction mixture and the reaction mixture was mixed for 20 minutes. The reaction mixture was then allowed to stand until the mixture separated into in an organic phase and an aqueous phase. The aqueous phase was then removed. After removing the aqueous phase from the reaction mixture, the organic phase was washed two more times with 200 grams of water. Finally, the organic phase was mixed with 100 grams of PGMEA and 50 grams of ethanol and placed on a rotary evaporator at 40° C. and under reduced pressure to remove any trace amounts of HCl. The organic phase was then diluted with PGMEA such that concentration of the polysilanesiloxane resin in the organic phase was 10.3 wt. % resin. The chloride content in the polysilanesiloxane was measured to be 0.061 wt. %. The organic phase was then stored for future use as the conventional ARC formulation from which an antireflective coating layer is formed on a substrate in Run No.'s 1-3.

### Example 2

Synthesis of D^{meH}_{0.1}T^{Me}_{0.1}T^{H}_{0.35}PSSX^{Me3si2O}_{0.15} PSSX^{Me2si2O}_{0.30} ARC Formulation

A 3-neck 2-liter flask equipped with a condenser, a heating mantle, a thermal couple, an addition funnel, and a magnet stirrer were assembled to form a reaction system. To this reaction system were added a first solution containing 4.6 grams of 50/50 MeHSiCl₂toluene, 12.0 grams of 50/50 MeSiCl₃toluene, 20.0 grams of 50/50 HSiCl₃toluene, 247 grams of propylene glycol methyl ether acetate (PGMEA), and 20.06 grams of distilled chloromethyldisilanes, which is composed of 6.7 grams of 1,1,2-trimethyltrichlorodisilane (Cl₃Me₃Si₂) and 13.3 grams of 1,1,2,2-tetramethyldichlorodisilane (Cl₂Me₄Si₂). A second solution containing 8.35 grams of water and 322.03 grams of PGMEA was fed into the flask using a MasterFlex® peristaltic metering pump over a period of 1.5 hours to form a reaction mixture. The reaction mixture was allowed to react further at 20° C. for an additional two hours. Then 200 grams of de-ionized water was added into the reaction mixture and the reaction mixture stirred for an additional 20 minutes. The reaction mixture was then allowed to stand until the mixture separated into an organic phase and an aqueous phase. The aqueous phase was then removed. After removing the aqueous phase from the reaction mixture, the organic phase was washed two more times with 200 grams of water. Finally, the organic phase was mixed with 100 grams of PGMEA and 50 grams of ethanol and placed on a rotary evaporator at 40° C. and reduced pressure to remove any trace amounts of HCl. The organic phase was then diluted with PGMEA such that concentration of the polysilanesiloxane resin in the organic phase was 9.94 wt. % resin. The chloride content in the polysilanesiloxane was measured to be 0.061 wt. %. The organic phase was then stored for future use as the ARC formulation from which an antireflective coating layer is formed on a substrate in Run No.'s 4-6.

A person skilled in the art will recognize that the measurements described above are standard measurements that can be obtained by a variety of different test methods. Any test methods described herein represents only one available method to obtain each of the required or desired measurements.

The foregoing description of various embodiments of the present disclosure has been presented for purposes of illustration and description. It is not intended to be exhaustive or to limit the present disclosure to the precise embodiments disclosed. Numerous modifications or variations are possible in light of the above teachings. The embodiments discussed were chosen and described to provide the best illustration of the principles included in the present disclosure and its practical application to thereby enable one of ordinary skill in the art to utilize the teachings of the present disclosure in various embodiments and with various modifications as are suited to the particular use contemplated. All such modifications and variations are within the scope of the present disclosure as determined by the appended claims when interpreted in accordance with the breadth to which they are fairly, legally, and equitably entitled.

What is claimed is:

1. An antireflective coating (ARC) formulation, the ARC formulation comprising a polysilanesiloxane resin and a solvent; the polysilanesiloxane resin comprising:
a first component defined by structural units of (R′)₂SiO₂;
a second component defined by structural units of (R″)SiO₃ and
a third component defined by structural units of (R′″)_{q+2}Si₂O_{4-q}
wherein R′, R″, and R′″ are independently selected to be hydrocarbon or hydrogen (H) groups; and the subscript q is 1 or 2.

2. The ARC formulation according to claim 1, wherein R′, R″, and R′″ are selected to be methyl (Me) or hydrogen (H) groups such that the structural units of (R′)₂SiO₂ are (Me)(H)SiO₂; the structural units of (R″)SiO₃ are a mixture of (H)SiO₃ and (Me)SiO₃; and R′″ and the structural units of (R′″ )_{q+2}Si₂O_{4-q} are a mixture of (Me)₃Si₂O₃ and (Me)₄Si₂O₂.

3. The ARC formulation according to claim 1, wherein in the polysilanesiloxane resin, the first component is present in a molar ratio x, the second component is present in molar ratio y, and the third component is present in a molar ratio z, such that (x+y+z)=1, x<y, and x<z.

4. The ARC formulation according to claim 3, wherein the molar ratio x equals 0.1, the molar ratio y equals 0.45, and the molar ratio z equals 0.45.

5. The ARC formulation according to claim 1, wherein the polysilanesiloxane resin comprises greater than or equal to 42 wt. % silicon.

6. The ARC formulation according to claim 1, wherein the solvent is an organic solvent or a silicone solvent.

7. The ARC formulation according to claim 1, wherein the ARC formulation further comprises one or more additives;
the additives being catalysts, surfactants, dispersants, or film forming aids.

8. A method of forming an antireflective coating (ARC), the method comprising the steps of:
providing a polysilanesiloxane resin dispersed in a solvent to form an ARC formulation; the polysilanesiloxane resin comprising:
a first component defined by structural units of (R′)₂SiO₂;
a second component defined by structural units of (R″)SiO₃; and
a third component defined by structural units of (R′″)_{q+2}Si₂O_{4-q}
wherein R′, R″, and R′″ are independently selected to be hydrocarbon or hydrogen (H) groups; and the subscript q is 1 or 2;
providing an electronic device;
applying the ARC formulation to the surface of the electronic device to form a film;
removing the solvent from the film; and
curing the film to form the antireflective coating.

9. The method according to claim 8, wherein the ARC formulation is applied to the surface of the electronic device by spin-coating.

10. The method according to claim 8, wherein the film is cured at a temperature less than or equal to 250° C.

11. The method according to claim 8, wherein the method further comprises the step of incorporating one or more additives into the ARC formulation.

12. The method according to claim 8, wherein the method further comprises the step of placing the film under an inert atmosphere prior to curing the film.

13. A substrate coated with an antireflective coating (ARC) layer, the ARC layer comprising a polysilanesiloxane resin, the polysilanesiloxane resin comprising D^{R}′, T^{R}″, and PSSX^{R}′″ structural units according to the formula:
(D^{R}′)ₓ (T^{R}″)_{y} (PSSX^{R}′″)_{Z}
wherein (D^{R}′)ₓ represents structural units of (R′)₂SiO₂; (T^{R}″)_{y} represents structural units of (R″)SiO₃; and (PSSX^{R}′″)_{z} represents structural units of (R′″ )_{q+2}Si₂O_{4-q}; R′, R″, and R′″ are independently selected to be hydrocarbon or hydrogen groups; and the subscript q is 1 or 2; with the subscripts x, y, and z representing mole fractions that are greater than zero and less than one, such that (x+y+z)=1.

14. The coated substrate according to claim 13, wherein the substrate is an electronic device.

15. The coated substrate according to claim 13, wherein R′, R″, and R′″ are selected to be methyl (Me) or hydrogen (H) groups such that the structural units of (R′)₂SiO₂ are (Me)(H)SiO₂; the structural units of (R″)SiO₃ are a mixture of (H)SiO₃ and (Me)SiO₃; and R′″ and the structural units of (R′″ )_{q+2}Si₂O_{4-q} are a mixture of (Me)₃Si₂O₃ and (Me)₄Si₂O₂.

16. The coated substrate according to claim 13, wherein in the polysilanesiloxane resin, the (D^{R}′)ₓ structural units, the (T^{R}″)_{y} structural units, and the (PSSX^{R}′″)_{z} structural units are present such that x<y, and x<z.

17. The coated substrate according to claim 16, wherein the molar ratio x equals 0.1, the molar ratio y equals 0.45, and the molar ratio z equals 0.45.

18. The coated substrate according to claim 13, wherein the polysilanesiloxane resin comprises greater than or equal to 42 wt. % silicon.
